(19) United States
(12) Patent Application Publication
(10) Pub. No.: US 2026/0320243 A1
(43) Pub. Date: Oct. 15, 2026

(54) ELECTROSTATIC DISCHARGE SIMULATOR INCLUDING PROGRAMMABLE CIRCUIT COMPONENT FOR DYNAMIC ADJUSTABILITY OF PULSE RISE TIME AND SLEW RATE

(71) Applicant: FEI Company, Hillsboro, OR (US)

(72) Inventor: Marcos HERNANDEZ, San Jose, CA (US)

(21) Appl. No.: 19/176,814

(22) Filed: Apr. 11, 2025

(51) Int. Cl. G06F 30/20

(52) U.S. Cl. CPC G06F 30/20

(57) ABSTRACT

An electrostatic discharge (ESD) simulator for discharging an ESD pulse to a device under test is disclosed. The ESD simulator comprises a gate driver, a switching circuit for controlling the discharge of the ESD pulse, wherein the switching circuit comprises at least one of a SiC or GaN transistor, and wherein the gate driver is connected to the switching circuit, and a programmable circuit component connected to the gate driver, wherein the programmable circuit component is adjustable, by a computing device, to change a current delivered to the switching circuit based on at least one of a desired pulse slew rate or desired pulse rise time defined by a user.

### BACKGROUND

Electrostatic discharge (ESD) simulators are devices used to generate electrostatic discharges for stressing electronic equipment such as integrated circuits, for example, with ESD events. ESD simulators assist in assessing how well electronic equipment can withstand sudden bursts of electrical energy caused by static electricity, which can occur during handling, operation, and/or environmental exposure. By simulating ESD events, ESD simulators help manufacturers and designers identify potential vulnerabilities and ensure their products meet industry standards for ESD protection, ultimately enhancing the reliability and longevity of electronic equipment.

### BRIEF DESCRIPTION OF THE DRAWINGS

Embodiments will be readily understood by the following detailed description in ‎conjunction with the accompanying drawings. To facilitate this description, like reference ‎numerals designate like structural elements. Embodiments are illustrated by way of ‎example, not by way of limitation, in the figures of the accompanying drawings.‎

FIG. 1 is a block diagram of an ESD simulator, in accordance with various embodiments;

FIG. 2 is an example of a protection circuit to be used in electronic equipment for diverting current away from sensitive components during an ESD event, in accordance with various embodiments;

FIG. 3 is a block diagram of an ESD simulator, in accordance with various embodiments;

FIG. 4 is a block diagram of an ESD simulator, in accordance with various embodiments;

FIG. 5 is an example ESD simulator, in accordance with various embodiments;

FIG. 6 is a block diagram of an ESD simulator support apparatus for performing support operations, in accordance with various embodiments;

FIG. 7 is a flow diagram of an example method of performing support operations, in accordance with various embodiments;

FIG. 8 is an example of a graphical user interface that may be used in the performance of some or all of the ESD simulator support methods disclosed herein, in accordance with various embodiments;

FIG. 9 is a block diagram of an example computing device that may perform some or all of the ESD simulator support methods disclosed herein, in accordance with various embodiments; and

FIG. 10 is a block diagram of an example ESD simulator support system in which some or all of the ESD simulator support methods disclosed herein may be performed, in accordance with various embodiments.

### DETAILED DESCRIPTION

Disclosed herein are electrostatic discharge simulators and support systems, as well as related methods, computing devices, and computer-readable media. For example, in some embodiments, an electrostatic discharge (ESD) simulator for discharging an ESD pulse to a device under test is disclosed. The ESD simulator comprises a gate driver, a switching circuit for controlling the discharge of the ESD pulse, wherein the switching circuit comprises at least one of a SiC or GaN transistor, and wherein the gate driver is connected to the switching circuit, and a programmable circuit component connected to the gate driver, wherein the programmable circuit component is adjustable, by a computing device, to change a current delivered to the switching circuit based on at least one of a desired pulse slew rate or desired pulse rise time defined by the user.

An electrostatic discharge (ESD) simulator is a device used to test electronic components and systems for their ability to withstand electrostatic discharge events. ESD simulators can generally be comprised of a high voltage power supply to generate the voltage for simulating the ESD event, a discharge network comprising various electrical components (such as resistors, capacitors, and/or inductors, for example) for shaping and storing an ESD pulse, a switching circuit for controlling the delivery of the ESD pulse to a device under test (DUT), a discharge tip through which the ESD pulse is discharged, an interface for controlling the ESD simulator, and a grounding system. The interface for controlling the ESD simulator can comprise a trigger mechanism to initiate the discharge event. The ESD simulator is designed to mimic the conditions under which an electrical charge might be transferred from a person or an object to an electronic device, potentially causing damage to the electronic components. The ESD simulator generates controlled, high-voltage discharges and applies them to a DUT.

Different types of stress models, defined by industry standards, are used to define the characteristics and/or test methods of a specific type of ESD event to be applied to a DUT. Such characteristics include ESD pulse amplitude, rise time, and slew rate, for example. The specific model corresponds to the potential sources of ESD events in the real world. Examples of such models include the Human Body Model (HBM) that aims to replicate the discharge of static electricity from a human body to an electronic device, Machine Model, Charged Device Model, System-Level ESD Model, Transmission Line Pulse Model, and Cable Discharge Event Model. One of the most prevalent standards defining the HBM is published by the Electrostatic Discharge Association (ESDA) as standard JS-001.

One or more characteristics of an ESD pulse generated by an ESD simulator may be defined by at least the specific circuitry chosen for the discharge network with the goal of replicating the stress models described herein. Conventional approaches for applying a Human Body Model ESD event, for example, to a DUT involve using a capacitor and a resistor in the discharge network to simulate the capacitance and resistance of a human body. During the test, the capacitor is charged to a high voltage and then discharged through the resistor into the device. This helps in assessing the device's robustness against a real-world HBM-like event, ensuring its reliability and safety when handled by people. However, such a discharge network is fixed and, without more, various characteristics of an ESD pulse discharged through such a discharge network cannot be dynamically adjusted without physically changing the circuitry of the ESD simulator or switching to entirely different discharge network. Discussed in greater detail herein, conventional approaches lack the ability to fine tune various characteristics of the ESD waveform on the fly without switching to a different discharge network.

The electronic components and/or equipment tested often contain one or more protection circuits to divert current from an ESD event to ground and away from sensitive electronic components. A simplified example of such a protection circuit can be seen in FIG. 2. As can be seen in FIG. 2, a protection circuit 100 can contain a resistor R and capacitor C which form a high pass filter and a transistor 102 (MOSFET (metal–oxide–semiconductor field-effect transistor), e.g.) that turns on when an ESD event is detected. When an ESD event is detected, the RC (resistor-capacitor) filter formed by the resistor R and the capacitor C is designed to cause the transistor 102 to turn on and divert the current to ground, avoiding the flow of current generated from the ESD event into the rest of the integrated circuit and, thus, preventing damage. The design of the RC filter is crucial to the operation of the protection circuit. This protection circuit 100 (also referred to as a protection structure), should remain off during normal operating voltages and current present at a given input node into the integrated circuit. The protection circuit 100 should turn on when an ESD event is present.

Due to the nature of some protection circuits such as the protection circuit 100, for example, the operation of the protection circuit becomes susceptible to the slew rate or rise time of the ESD event. In other words, the variation of the rate at which the ESD event is discharged as well as the time it takes to reach a peak pulse amplitude of the ESD event affect the performance of the protection circuit such as how effectively the protection circuit redirects current generated from the ESD event to ground. If the rise time is too short, the slew rate is too quick, the rise time is too long, or the slew rate is too slow, for example, the protection circuit may not be able to effectively direct the current to ground thereby damaging the circuitry of the electrical equipment, for example. This sensitivity to slew rate and/or rise time variation can result in a scenario where during one ESD testing of a particular piece of electrical equipment (potentially of a higher sensitivity to slew rate and/or rise time variation), the circuit may pass the test (not fail, for example) when using a first slew rate and/or rise time but, in a field scenario, the circuit may fail in the field where the slew rate and/or rise time of the actual ESD event experienced by the circuit may have just a slight change of slew rate and/or rise time that is different than the first slew rate and/or rise time used during ESD simulation testing.

Because of this variability in the performance of the protection circuit due to different pulse characteristics such as slew rate and rise time, for example, there is a need to be able to dynamically and directly control, during ESD testing, ESD pulse characteristics (slew rate and rise time, for example) using a user-defined slew rate and/or rise time, for example, to be able to characterize the effects of varying slew rate and rise time, for example, during testing of electronic equipment to enhance test findings and, ultimately, improve protection circuit design. Embodiments disclosed herein allow for the dynamic adjustment of the slew rate and/or rise time of the ESD pulse generated by the ESD simulator directly without switching discharge networks (different circuits for shaping pulses having different characteristics). This fine tuning of slew rate and/or rise time, for example, allows equipment to be tested with ESD pulses having custom defined characteristics beyond just amplitude, for example.

In conventional ESD simulators, the capacitor and the resistor are preselected and installed in the ESD simulators by the manufacture of the ESD simulator to provide an end user with a HBM pulse option, for example, to specifically mimic the HBM. The specific capacitance of the capacitor and the resistance of the resistor define certain characteristics of the waveform of the ESD pulse applied to the DUT in an attempt to conform with industry standards. A user cannot change or finetune certain characteristics of the ESD pulse without rebuilding the discharge network. Further, supplying an ESD simulator with many discharge networks is costly, complex, and increases unreliability. Even with many discharge networks, such an ESD simulator still lacks the dynamic, direct, and customized control of certain ESD characteristics. Because the capacitor and resistor are preselected and preinstalled in the ESD simulator, the specifications of the capacitor and resistor are fixed within the ESD simulator, leaving users without the ability to adjust the ESD pulse characteristics quickly, efficiently, or with high precision. For example, having five different discharge networks may only provide five different fixed pulse profiles. If one of the five pulse profiles does not fit every characteristic desired by the user, the user cannot test with an ESD pulse having the desired characteristics. Conventional approaches do not provide the ability to have user-defined slew rate and/or rise time to adjust ESD pulse characteristics.

Further to the above, industry standards may require a particular range of slew rate and/or rise time values of ESD pulses being discharged into a DUT during testing. In conventional devices, manufacturers simply design the circuit to fall within that range (a rise time between 3 nanoseconds and 10 nanoseconds, for example). If the circuit produces an ESD pulse with a slew rate and/or rise time within the industry-specified range, the ESD simulator is deemed adequate for testing and is ready to be used for testing. However, as discussed herein, various types of circuits are more sensitive to slight changes in slew rate and/or rise time of ESD events. Thus, there is a need to be able to finely control the slew rate and/or rise time of the ESD pulse delivered to a device under test across the industry-specified range. Embodiments disclosed herein allow for testing of many different slew rates and/or rise times across the industry-specified range in addition to slew rates and/or rise times outside of the industry-specified range if desired. In at least one instance, the worst-case scenario of an ESD event is when the rise time is the shortest and/or the slew rate is the fastest. Embodiments disclosed herein allow a user to tune the slew rate and/or rise time to define the ESD pulses on the fly according to the worst-case scenarios.

Further to the above, as electrical components in one or more discharge networks vary in physical properties with age, for example, the waveform characteristics discussed herein of the ESD pulse may also vary over time as a result. This introduces unpredictability and lessens the accuracy of the waveform characteristics of the ESD pulse over time from a nominal value. Embodiments disclosed herein allow for the fine tune control of those characteristics to remedy component age-related effects on the pulse characteristics. In other words, as components move away from nominal specifications and, as a result, affect pulse characteristics, the embodiments disclosed herein can either automatically, or by a user, make adjustments to a programmable circuit component to account for the variances in the pulse characteristics to bring the pulse characteristics back toward or to nominal operating expectations.

Embodiments disclosed herein allow for more consistent (with respect to rise time and/or slew rate, for example) ESD pulse waveforms originating from many different pulse sources. The rise time and/or slew rate can be affected by the length of the trace between ground and stress when testing a device. Different pulse sources can be selected so that resulting waveform is within the slew rate and/or rise time industry-defined specification. If a user tests a pin with a long trace (higher inductance), the slew rate and/or rise time of the resulting discharged ESD pulse may fall out of the industry-specified range. A different pulse source is then selected in an effort to move the slew rate and/or rise time to within the industry-specified range. Embodiments disclosed herein allow for adjustment of slew rate and/or rise time of a single pulse source. In at least one instance, having many different pulse sources and the ability to adjust the resulting slew rate and/or rise time of ESD pulses generated with each pulse source provides much greater flexibility during testing.

Embodiments disclosed herein include an ESD simulator having at least one programmable circuit component dynamically adjustable by a computing device in response to a user-defined rise time and/or slew rate. The at least one programmable circuit may comprise a programmable power supply and/or a programmable variable resistor, discussed in greater detail below. This allows a user to change the slew rate and/or rise time of the ESD pulse without requiring the user to physically swap hardware components of the discharge network and without requiring the ESD simulator to have many discharge networks having many different rise times and/or slew rates (which still lacks fine-tune control, increases complexity and cost, and reduces reliability). With the embodiments disclosed herein, a user can vary the rise time and/or slew rate of the ESD pulse on the fly to determine what effect(s) these changes have on the DUT.

In embodiments disclosed herein, a computing device can automatically change rise time and/or slew rate of the ESD pulse in response to measured ESD pulse feedback, for example. In at least one instance, the programmable circuit component comprises a variable resistor. In at least one instance, the programmable circuit component includes a programmable power supply. In at least one instance, the programmable circuit component includes both a variable resistor and a programable power supply.

Embodiments disclosed herein allow a user to quickly and efficiently change the characteristics of the ESD pulse. Embodiments disclosed herein can further allow a user and/or computing device to monitor an actual slew rate and/or rise time of the ESD pulse delivered to a DUT to ensure the discharged ESD pulse is behaving as expected (according to the user-defined ESD pulse characteristic or at least within a predefined threshold of similarity (1%, 5%, 10%, and/or a user-defined percentage), for example). Adjustments can be made automatically by the computing device or manually by a user to further fine tune the rise time and/or slew rate of the ESD pulse to be discharged into a DUT. In at least one instance, a computing device can recommend a specific adjustment after an ESD pulse is generated in an effort to generate a subsequent ESD pulse with an actual ESD characteristic closer to the user-defined ESD pulse characteristic. The recommendation can be based on the ESD characteristic monitored from the prior ESD pulse.

Embodiments disclosed herein can be used with any of the systems, circuits, apparatuses, and/or methods, disclosed in U.S. Patent No. 11,846,664 entitled “SOLID STATE ESD SIC SIMULATOR” and issued on Dec. 19, 2023, the entirety of which is incorporated by reference herein in its entirety.

The embodiments disclosed herein may achieve more robust ESD simulator testing relative to conventional approaches. For example, conventional approaches are limited in what characteristics of ESD pulses are definable by a user, for example and limited in how different types of ESD pulses are selected, modified, and discharged. However, these approaches suffer from a number of technical problems and limitations, including the inability to dynamically change and define various ESD pulse characteristics according to user-defined desired characteristics such as slew rate and/or rise time. These approaches also do not provide the ability to monitor and provide feedback of discharged ESD pulses to make further adjustments on the fly based on the monitored ESD pulses. These approaches also lack the ability to provide fine tune control of various characteristics. These approaches also suffer from device complexity with respect to requiring many different discharge networks to supply different ESD pulse characteristics.

Various ones of the embodiments disclosed herein may improve upon conventional approaches to achieve the technical advantages of characterizing the effects of different slew rates and/or rise times of ESD events on electrical equipment by providing an ESD simulator and support systems which allow for dynamic control of various ESD pulse characteristics without requiring different discharge networks. Such technical advantages are not achievable by routine and conventional approaches, and all users of systems including such embodiments may benefit from these advantages (e.g., by assisting the user in the performance of a technical task, such as on the fly control of ESD pulse waveform characteristics with an ESD simulator, by means of a guided human-machine interaction process). The technical features of the embodiments disclosed herein are thus decidedly unconventional in the field of ESD simulation and testing, as are the combinations of the features of the embodiments disclosed herein. As discussed further herein, various aspects of the embodiments disclosed herein may improve the functionality of a computer itself; for example, providing fine tune control of ESD pulse waveform characteristics, providing a feedback loop to further tune the resulting and subsequent ESD pulse characteristics, and providing the automatic adjustment of digital circuit components to achieve desired ESD pulse characteristics. The computational and user interface features disclosed herein do not only involve the collection and comparison of information, but apply new analytical and technical techniques to change the operation of ESD simulators. The present disclosure thus introduces functionality that neither a conventional computing device, nor a human, could perform.

Accordingly, the embodiments of the present disclosure may serve any of a number of technical purposes, such as controlling a specific technical system or process; determining from measurements how to control a machine; simulating the behavior of a technical item or process; providing a faster processing of sensor data, determining from measurements electrical equipment’s ability to handle ESD events as it relates specifically to different slew rates and/or rise times of the ESD event, or controlling ESD pulse characteristics of an ESD simulator during ESD testing.

The embodiments disclosed herein thus provide improvements to ESD simulation technology (e.g., improvements in the computer technology supporting ESD simulation, among other improvements).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the subject matter disclosed herein. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrases "A and/or B" and "A or B" mean (A), (B), or (A and B). For the purposes of the present disclosure, the phrases "A, B, and/or C" and "A, B, or C" mean (A), (B), (C), (A and B), (A and C), (B and C), or (A, B, and C). Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices.

The description uses the phrases "an embodiment," “various embodiments,” and "some embodiments," each of which may refer to one or more of the same or different embodiments. Furthermore, the terms "comprising," "including," "having," and the like, as used with respect to embodiments of the present disclosure, are synonymous. When used to describe a range of dimensions, the phrase "between X and Y" represents a range that includes X and Y. As used herein, an “apparatus” may refer to any individual device or collection of devices. The drawings are not necessarily to scale.

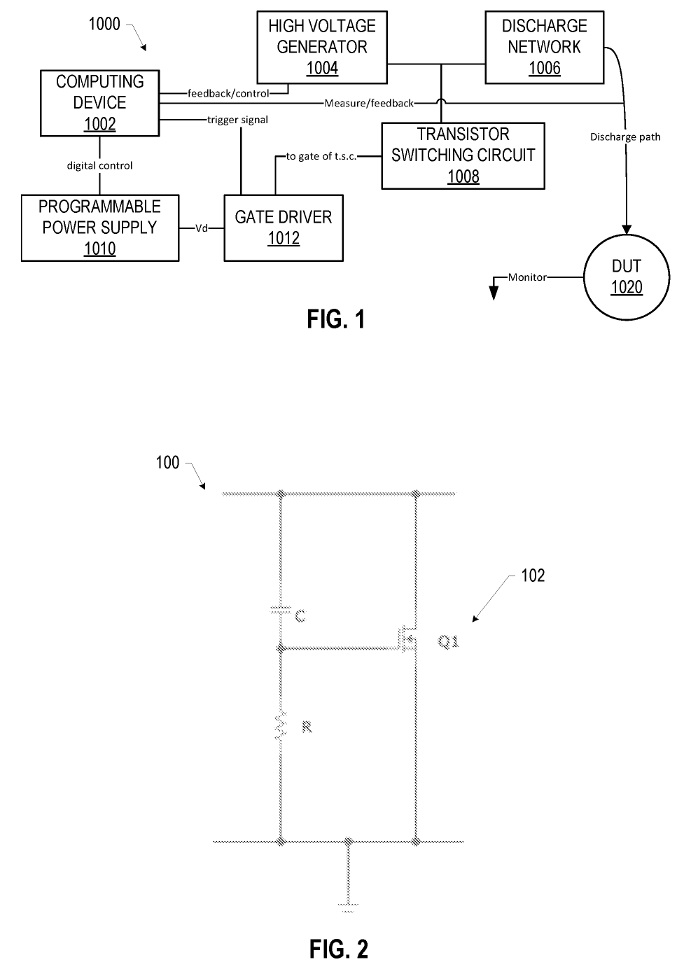

FIG. 1 depicts an ESD simulator 1000 for generating an ESD pulse and delivering the ESD pulse to a device under test (DUT) 1020, in accordance with various embodiments disclosed herein. The ESD simulator 1000 comprises a computing device 1002, a high voltage generator 1004, a discharge network 1006, and a transistor switching circuit 1008. In at least one instance, the transistor switching circuit 1008 is referred to as a pulser. The high voltage generator 1004 is controllable by the computing device 1002 and is configured to charge one or more capacitors in the discharge network 1006. The discharge network 1006 can comprise one or more electrical components for shaping the waveform of the ESD pulse. The transistor switching circuit 1008 comprises one or more transistors to control the delivery of the ESD pulse to the DUT 1020. The transistor switching circuit 1008 comprises at least one of a SiC or GaN transistor. Examples of transistor arrangements can be seen in U.S. Patent No. 11,846,664 entitled “SOLID STATE ESD SIC SIMULATOR” and issued on Dec. 19, 2023.

The transistor switching circuit 1008 is connected to a gate driver 1012. The gate driver 1012 is configured to provide the necessary signal to switch one or more gates of the transistor(s) of the transistor switching circuit 1008. The gate driver 1012 is supplied a gate driver voltage Vd by a programmable power supply 1010. A trigger signal is delivered to the gate driver 1012 by way of the computing device 1002 to switch the transistor switching circuit 1008 and, thus, discharge an ESD pulse. When an ESD pulse is stored and, ultimately, discharged through the discharge network 1006 by the transistor switching circuit 1008, the ESD pulse is delivered to the DUT 1020 through a discharge tip, for example.

In at least one instance, the computing device 1002 is configured to measure one or more actual characteristics of the ESD pulse (voltage, current, pulse amplitude, slew rate, and/or rise time) delivered to the DUT 1020. In at least one instance, the computing device 1002 and/or another measurement device is used to monitor the DUT 1020 to monitor the effects of discharged ESD pulses on the circuitry of the DUT 1020.

The programmable power supply 1010 is adjustable by the computing device 1002 to control the gate driver voltage Vd. Changing the gate driver voltage Vd changes the current that flows into the gate of the transistor switching circuit 1008. Changing the current that flows into the gate of the transistor switching circuit 1008 changes switching behavior of the transistor switching circuit 1008. Changing the switching behavior of the transistor switching circuit 1008 changes the rise time and/or slew rate of the ESD pulse to be discharged. A Silicon Carbide SiC, for example, typically has a gate driving voltage of -5V for the off state and +20V for the on state, lowering the turn on voltage to +18V will result in a slower rise time on the output as compared to +20V.

As discussed herein, the computing device 1002 is to receive a desired pulse slew rate and/or rise time by a user (and/or automatically receive a desired pulse slew rate and/or rise time) and is to adjust the gate driver voltage Vd corresponding to the desired pulse slew rate and/or rise time to cause the ESD pulse to be discharged to exhibit the desired pulse slew rate and/or rise time. As discussed herein, the effects of the ESD pulse can be monitored through additional monitoring connections connected to the DUT 1020 so that different slew rates and/or rise times of ESD pulses can be characterized during testing.

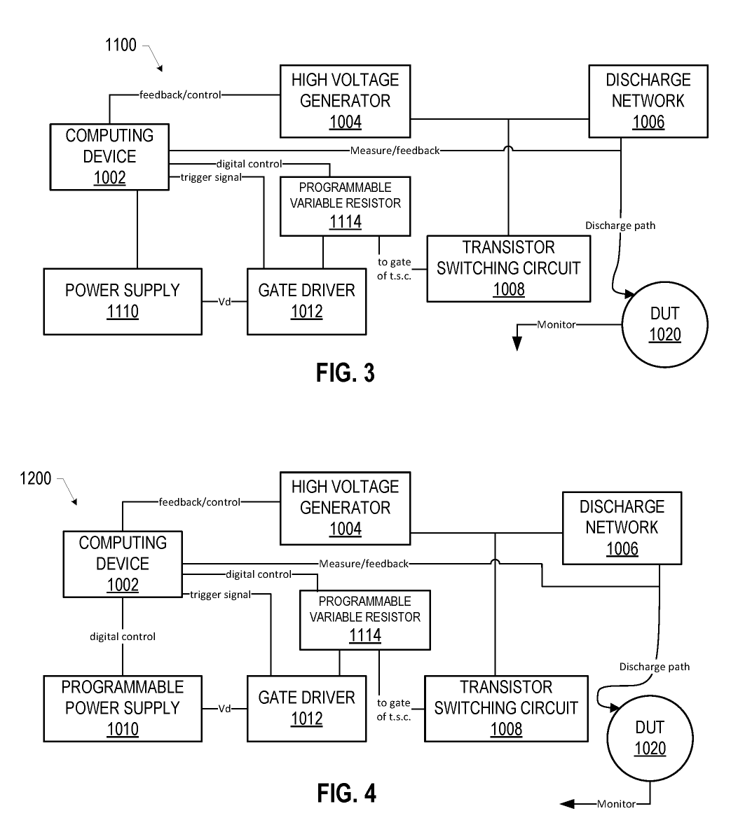

FIG. 3 depicts an ESD simulator 1100 in accordance with various embodiments disclosed herein. The ESD simulator 1100 may be similar to the ESD simulator 1000 except for the differences discussed below. The ESD simulator 1100 comprises a power supply 1110 to supply gate driver voltage Vd to the gate driver 1012 and a programmable variable resistor 1114 to control the current that flows into the gate(s) of the transistor switching circuit 1008. The programmable variable resistor 1114 is connected between the gate driver 1012 and the one or more gates of the transistor switching circuit 1008. The programmable variable resistor 1114 is digitally adjustable by the computing device 1002 to change the current that flows into the transistor switching circuit 1008. As discussed herein, changing the current that flows into the one or more gates of the transistor switching circuit 1008 changes the rise time and/or slew rate of the ESD pulse to be discharged. The programmable variable resistor 1114 is configured to be adjusted in response to a desired slew rate and/or rise time of an ESD pulse received by the computing device 1002 to cause the ESD pulse to be discharged to exhibit the desired pulse slew rate and/or rise time.

FIG. 4 depicts an ESD simulator 1200 in accordance with various embodiments disclosed herein. The ESD simulator 1200 may be similar to the ESD simulators 1000 and 1100 except for the differences discussed below. The ESD simulator 1200 comprises both the programmable power supply 1010 to digitally control the gate driver voltage Vd and the programmable variable resistor 1114 to control the flow of current into the transistor switching circuit 1008. Adjustments to each of the programmable power supply 1010 and the programmable variable resistor 1114 affect the current delivered to the one or more gates of the transistor switching circuit 1008 and, thus, can provide greater fine tune control of the current (and, thus, the slew rate and rise time of the resulting ESD pulse) that flows into the transistor switching circuit 1008. In at least one instance, a user is able to lock, via a user interface on a display, one of the gate driver voltage Vd or the resistance of the programmable variable resistor 1114 so that the computing device 1002 only adjusts the non-locked programmable circuit component to achieve the desired ESD pulse slew rate and/or rise time. In at least one instance, the computing device 1002 adjusts one of the programmable circuit components for broader control of the resulting ESD pulse slew rate and/or rise time and adjusts the other of the programmable circuit components for a finer control of the resulting ESD pulse slew rate and/or rise time.

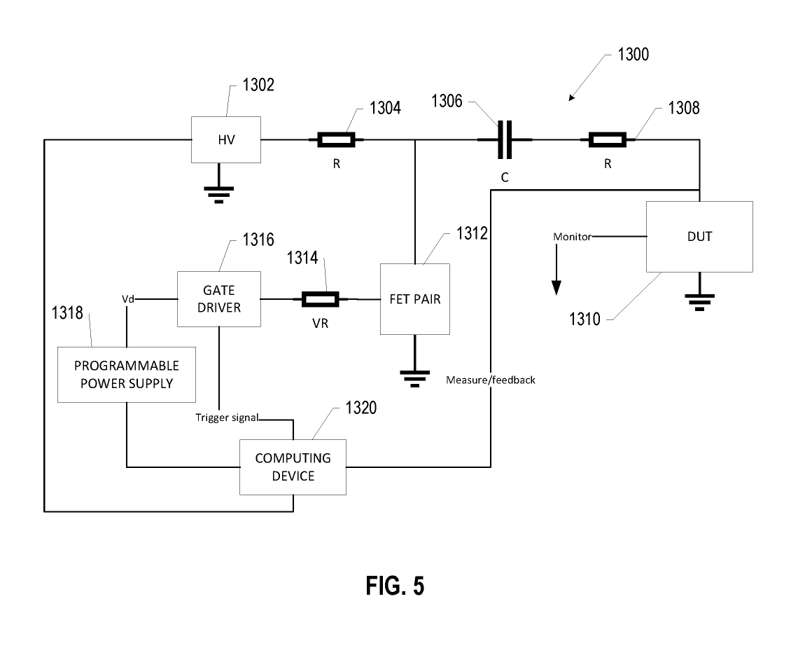

FIG. 5 depicts a circuit 1300 of an ESD simulator in accordance with various embodiments disclosed herein. The circuit 1300 comprises a high voltage power supply 1302, a current regulation resistor 1304, a discharge network including a capacitor 1306 and resistor 1308, and an FET pair 1312 for controlling the deliver of the ESD pulse through the discharge network. While a pair of FETs is illustrated in FIG. 5, other configurations of field effect transistors can be used. The high voltage power supply 1302 is configured to charge the discharge network. In at least one instance, a voltage is specified by a user and the high voltage power supply 1302 is adjusted corresponding to the user-specified voltage.

The circuit 1300 further comprises a computing device 1320, a programmable power supply 1318, a gate driver 1316, and a programmable variable resistor 1314. As discussed herein, only one of a programmable power supply or a variable resistor may be employed to control the current that flows into the gate of the FET pair 1312 to achieve desired slew rates and/or rise times. The programmable power supply 1318 supplies the gate driver voltage Vd to the gate driver 1316. The gate driver 1316 controls the switching of the FET pair 1312.

The computing device 1320 is configured to receive a desired slew rate and/or rise time and, in response, adjust one or both the programmable power supply 1318 and the variable resistor 1314 to adjust the current that flows into the gates of the FET pair 1312 to thereby change the slew rate and/or rise time of the ESD pulse generated by the circuit 1300 to exhibit the desired slew rate and/or rise time. In at least one instance, the circuit 1300 is further configured to measure the discharged ESD pulse as it is discharged and compare one or more measured characteristics to the desired characteristics (slew rate and/or rise time). In at least one instance, the computing device 1320 is configured to display the comparison, display the measured values, and/or recommend a further adjustment based on a discrepancy between the desired values and measured values.

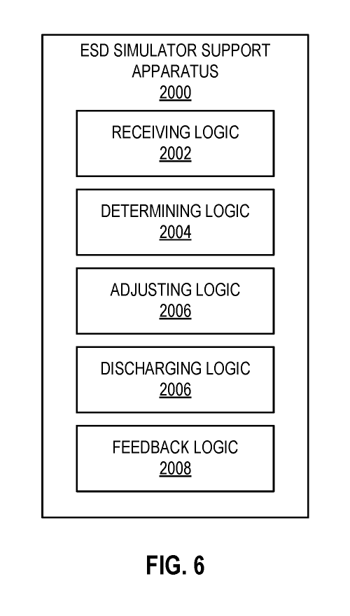

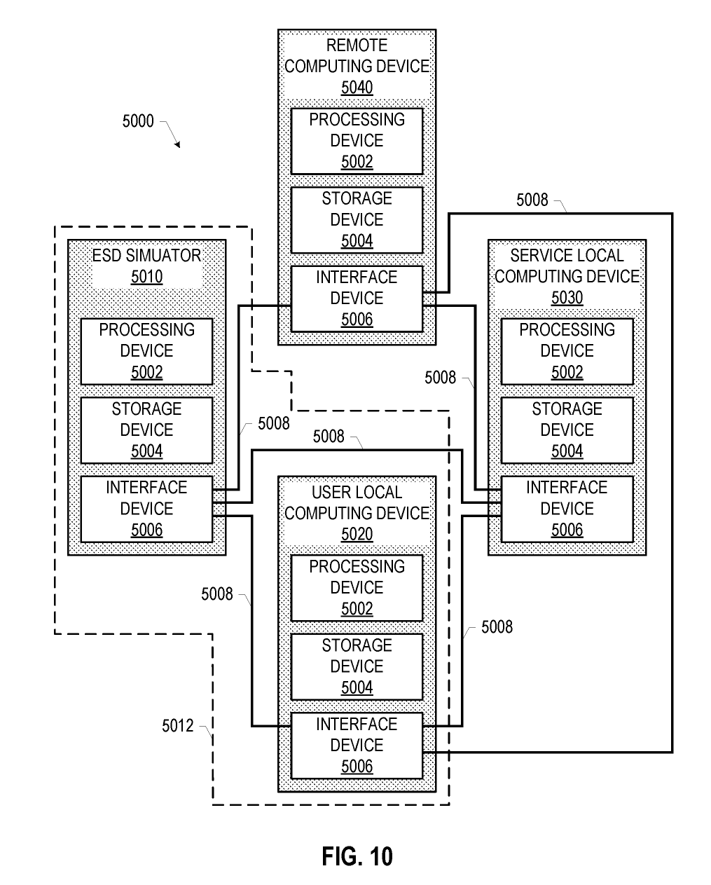

FIG. 6 is a block diagram of an ESD simulator support apparatus 2000 for performing support operations in accordance with various embodiments. The ESD simulator support apparatus 2000 may be implemented by circuitry (e.g., including electrical and/or optical components), such as a programmed computing device. The logic of the ESD simulator support apparatus 2000 may be included in a single computing device, or may be distributed across multiple computing devices that are in communication with each other as appropriate. Examples of computing devices that may, singly or in combination, implement the ESD simulator support apparatus 2000 are discussed herein with reference to the computing device 4000 of FIG. 9, and examples of systems of interconnected computing devices, in which the ESD simulator support apparatus 2000 may be implemented across one or more of the computing devices, is discussed herein with reference to the ESD simulator support system 5000 of FIG. 10.

The ESD simulator support apparatus 2000 may include receiving logic 2002, determining logic 2004, adjusting logic 2006, discharging logic 2008, and feedback logic 2010. As used herein, the term “logic” may include an apparatus that is to perform a set of operations associated with the logic. For example, any of the logic elements included in the ESD simulator support apparatus 2000 may be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” may refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices.

The receiving logic 2002 is configured to receive a desired characteristic of the ESD pulse to be generated and discharged by an ESD simulator. The desired characteristic may include any suitable characteristic such as, for example, slew rate and/or rise time of an ESD pulse. In at least one instance, the desired characteristic received by the receiving logic 2002 is in addition to one or more other desired characteristics of the ESD pulse such as amplitude, for example. At any rate, the receiving logic 2002 may receive the desired characteristic by a user defining and/or selecting a value of the desired characteristic through a user interface provided via a display, for example. In such an instance, a user can input one or more desired characteristics via the user interface. In at least one instance, the receiving logic 2002 may receive the desired characteristic automatically through a feedback loop where an actual measured characteristic value of the ESD pulse does not match an expected characteristic value, discussed in greater detail below. The expected characteristic value can be synonymous with the received desired characteristic. In at least one instance, more than one characteristics are measured and received by the receiving logic 2002 through the feedback loop.

The determining logic 2004 is configured to determine an adjustment to be made to at least one programmable circuit component to ensure that the ESD pulse exhibits the received desired characteristic. As discussed herein, the at least one programmable circuit component comprises a programmable power supply supplying a gate driver voltage Vd, a programmable variable resistor controlling the current flowing into one or more gates of a switching circuit, or both a programmable power supply and a programmable variable resistor. In at least one instance, the determining logic 2004 can utilize a predefined table having a range of adjustable values (gate driver voltages and/or resistance values, for example) and corresponding ESD pulse characteristics to determine the adjustment to be made to the at least one programmable circuit component which would result in an ESD pulse having the received desired characteristic. Other determining logic is contemplated.

The adjusting logic 2006 is to adjust the at least one programmable circuit component according to the determined adjustment. The adjusting logic 2006 adjusts, via a computing device, the gate driver voltage through the programmable power supply and/or the resistance of the programmable variable resistor.

The discharging logic 2008 is configured to discharge the ESD pulse after the adjustment is made to the at least one programmable circuit components. Discharging the ESD pulse can involve a user initiating the discharge through a trigger via a user interface, for example. In at least one instance, a computing device sends a trigger signal to a gate driver to control a switching circuit to deliver the ESD pulse.

The feedback logic 2010 is configured to measure the ESD pulse during discharge. In at least one instance, the feedback logic 2010 measures and records the one or more characteristics corresponding to the received characteristics of the discharged ESD pulse and compares the measured values to the received values. In at least one instance, the measured values are displayed to a user via a display. In at least one instance, any discrepancy is highlighted for a user. In at least one instance, the determining logic 2004 determines a further adjustment to be made to at least one programmable circuit component based on any discrepancy and the feedback logic 2010 recommends to a user through the display the further adjustment. In at least one instance, the further adjustment is automatically determined and at least one programmable circuit component is automatically adjusted for a subsequent ESD pulse in an effort to ensure that the resulting ESD pulse has an actual value closer to the received characteristic defined by the user.

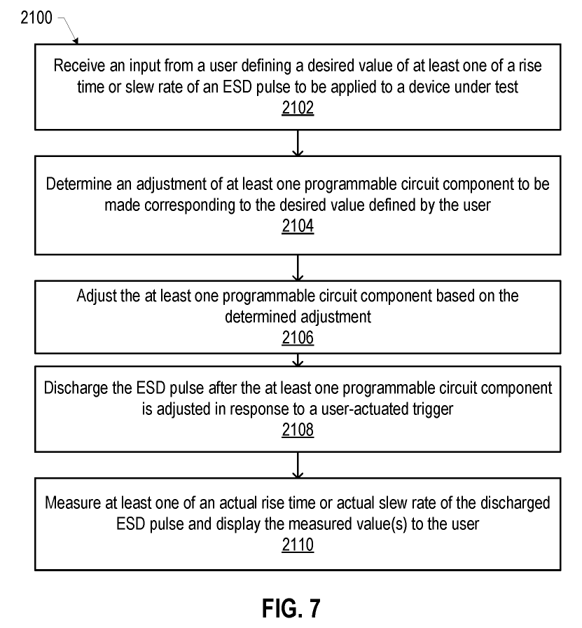

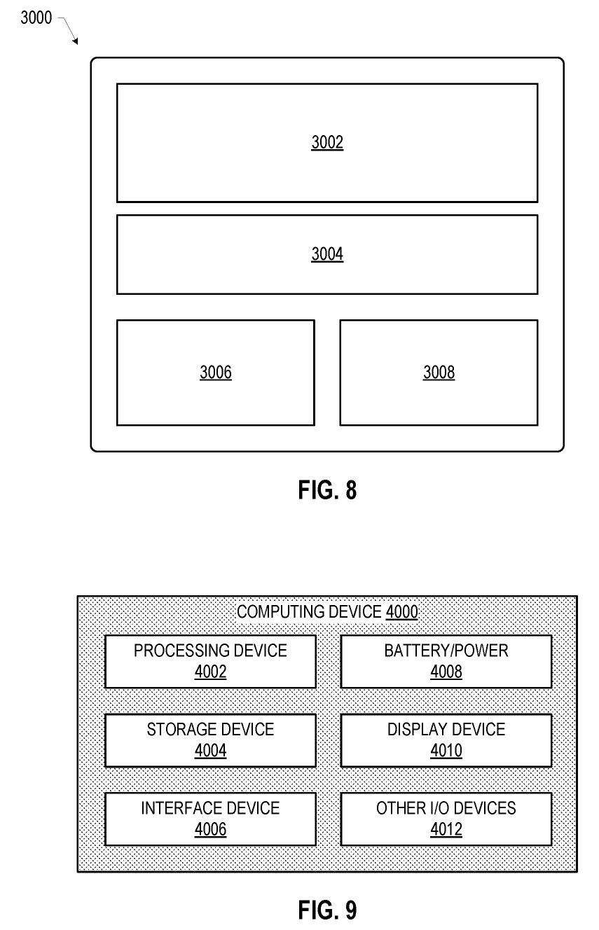

FIG. 7 is a flow diagram of a method 2100 of performing support operations, in accordance with various embodiments. Although the operations of the method 2100 may be illustrated with reference to particular embodiments disclosed herein (e.g., the ESD simulator support apparatus 2000 discussed herein with reference to FIG. 6, the GUI 3000 discussed herein with reference to FIG. 8, the computing devices 4000 discussed herein with reference to FIG. 9, and/or the ESD simulator support system 5000 discussed herein with reference to FIG. 10), the method 2100 may be used in any suitable setting to perform any suitable support operations. Operations are illustrated once each and in a particular order in FIG. 7, but the operations may be reordered and/or repeated as desired and appropriate (e.g., different operations performed may be performed in parallel, as suitable).

At 2102, first operations may be performed. For example, the receiving logic 2002 of the ESD simulator support apparatus 2000 may perform the operations of 2102. The first operations may include receiving an input from a user defining a desired value of at least one of rise time or slew rate of an ESD pulse to be applied to a device under test.

At 2104, second operations may be performed. For example, the determining logic 2004 of the ESD simulator support apparatus 2000 may perform the operations of 2104. The second operations may include determining an adjustment of at least one programmable circuit component to be made corresponding to the desired value defined by the user.

At 2106, third operations may be performed. For example, the adjusting logic 2006 of the ESD simulator support apparatus 2000 may perform the operations of 2106. The third operations may include adjusting the at least one programmable circuit component based on the determined adjustment.

At 2108, fourth operations may be performed. For example, the discharging logic 2008 of the ESD simulator support apparatus 2000 may perform the operations of 2108. The fourth operations may include discharging the ESD pulse after the at least one programmable circuit component is adjusted in response to a user-actuated trigger.

At 2110, fifth operations may be performed. For example, the feedback logic 2010 of the ESD simulator support apparatus 2000 may perform the operations 2110. The fifth operations may include measuring at least one of an actual rise time or actual slew rate of the discharged ESD pulse and display the measured value(s) to a user. In at least one instance, the fifth operations further includes recommending a further adjustment of the at least one programmable circuit component to a user in an attempt to bring the actual ESD pulse characteristics closer to the desired values. In at least one instance, such a further adjustment is automatically made by the ESD simulator support apparatus 2000 for subsequent ESD pulses to be discharged.

The ESD simulator support methods disclosed herein may include interactions with a human user (e.g., via the user local computing device 5020 discussed herein with reference to FIG. 10). These interactions may include providing information to the user (e.g., information regarding the operation of an ESD simulator such as the ESD simulator 5010 of FIG. 10, information regarding equipment being analyzed or other test or measurement performed by an ESD simulator, information retrieved from a local or remote database, or other information) or providing an option for a user to input commands (e.g., to control the operation of an ESD simulator such as the ESD simulator 5010 of FIG. 10, or to control the analysis of data generated by an ESD simulator), queries (e.g., to a local or remote database), or other information. In some embodiments, these interactions may be performed through a graphical user interface (GUI) that includes a visual display on a display device (e.g., the display device 4010 discussed herein with reference to FIG. 9) that provides outputs to the user and/or prompts the user to provide inputs (e.g., via one or more input devices, such as a keyboard, mouse, trackpad, or touchscreen, included in the other I/O devices 4012 discussed herein with reference to FIG. 9). The ESD simulator support systems disclosed herein may include any suitable GUIs for interaction with a user.

FIG. 8 depicts an example GUI 3000 that may be used in the performance of some or all of the support methods disclosed herein, in accordance with various embodiments. As noted above, the GUI 3000 may be provided on a display device (e.g., the display device 4010 discussed herein with reference to FIG. 9) of a computing device (e.g., the computing device 4000 discussed herein with reference to FIG. 9) of an ESD simulator support system (e.g., the ESD simulator support system 5000 discussed herein with reference to FIG. 10), and a user may interact with the GUI 3000 using any suitable input device (e.g., any of the input devices included in the other I/O devices 4012 discussed herein with reference to FIG. 9) and input technique (e.g., movement of a cursor, motion capture, facial recognition, gesture detection, voice recognition, actuation of buttons, etc.).

In at least one instance, an ESD simulator can include more than one transistor switching circuit arrangement having different arrangements of transistors to vary the rise time and/or slew rate of ESD pulses. In such an instance, a user and/or a computing device can switch between the different transistor switching circuit arrangements according to a user-defined slew rate and/or rise time.

The GUI 3000 may include a data display region 3002, a data analysis region 3004, an ESD simulator control region 3006, and a settings region 3008. The particular number and arrangement of regions depicted in FIG. 8 is simply illustrative, and any number and arrangement of regions, including any desired features, may be included in a GUI 3000.

The data display region 3002 may display data generated by an ESD simulator and/or other measurement apparatuses used in conjunction with an ESD simulator (e.g., the ESD simulator 5010 discussed herein with reference to FIG. 10). For example, the data display region 3002 may display feedback measurements of ESD pulses generated by an ESD simulator, recommended adjustments to make to at least one programmable circuit component, a variable control or manual input section for inputting desired value of one or more ESD pulse characteristics, and/or predefined profiles of ESD pulse characteristics to be selected by a user.

The data analysis region 3004 may display the results of data analysis (e.g., the results of analyzing the data illustrated in the data display region 3002 and/or other data). In some embodiments, the data display region 3002 and the data analysis region 3004 may be combined in the GUI 3000 (e.g., to include data output from an ESD simulator and/or corresponding measurement apparatus, and some analysis of the data, in a common graph or region).

The ESD simulator control region 3006 may include options that allow the user to control an ESD simulator (e.g., the ESD simulator 5010 discussed herein with reference to FIG. 10). For example, the ESD simulator control region 3006 may include an area to define one or more ESD pulse characteristics where a user can manually input a desired value for one or more ESD pulse characteristics such that a corresponding adjustment to at least one programmable circuit component that would result in an ESD pulse exhibiting such desired characteristics can be made by the ESD simulator. Such areas may include fine tune control knobs or data entry fields, for example. Such areas may include a slider with definable minimums and maximums of such ESD pulse characteristics.

The settings region 3008 may include options that allow the user to control the features and functions of the GUI 3000 (and/or other GUIs) and/or perform common computing operations with respect to the data display region 3002 and data analysis region 3004 (e.g., saving data on a storage device, such as the storage device 4004 discussed herein with reference to FIG. 9, sending data to another user, labeling data, etc.). For example, the settings region 3008 may include options to adjust or not adjust one or more of the at least one programmable circuit components. For example, a user may select/unselect the programmable power supply and the programmable variable resistor as programmable circuit components to be adjusted (or not adjusted as the case may be) in response to a user-defined, or automatic, desired ESD pulse characteristic.

As noted above, the ESD simulator support apparatus 2000 may be implemented by one or more computing devices. FIG. 9 is a block diagram of a computing device 4000 that may perform some or all of the ESD simulator support methods disclosed herein, in accordance with various embodiments. In some embodiments, the ESD simulator support apparatus 2000 may be implemented by a single computing device 4000 or by multiple computing devices 4000. Further, as discussed below, a computing device 4000 (or multiple computing devices 4000) that implements the ESD simulator support apparatus 2000 may be part of one or more of the ESD simulator 5010, the user local computing device 5020, the service local computing device 5030, or the remote computing device 5040 of FIG. 10.

The computing device 4000 of FIG. 9 is illustrated as having a number of components, but any one or more of these components may be omitted or duplicated, as suitable for the application and setting. In some embodiments, some or all of the components included in the computing device 4000 may be attached to one or more motherboards and enclosed in a housing (e.g., including plastic, metal, and/or other materials). In some embodiments, some these components may be fabricated onto a single system-on-a-chip (SoC) (e.g., an SoC may include one or more processing devices 4002 and one or more storage devices 4004). Additionally, in various embodiments, the computing device 4000 may not include one or more of the components illustrated in FIG. 9, but may include interface circuitry (not shown) for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 4000 may not include a display device 4010, but may include display device interface circuitry (e.g., a connector and driver circuitry) to which a display device 4010 may be coupled.

The computing device 4000 may include a processing device 4002 (e.g., one or more processing devices). As used herein, the term "processing device" may refer to any device or portion of a device that processes electronic data from registers and/or memory to transform that electronic data into other electronic data that may be stored in registers and/or memory. The processing device 4002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 4000 may include a storage device 4004 (e.g., one or more storage devices). The storage device 4004 may include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 4004 may include memory that shares a die with a processing device 4002. In such an embodiment, the memory may be used as cache memory and may include embedded dynamic random access memory (eDRAM) or spin transfer torque magnetic random access memory (STT-MRAM), for example. In some embodiments, the storage device 4004 may include non-transitory computer readable media having instructions thereon that, when executed by one or more processing devices (e.g., the processing device 4002), cause the computing device 4000 to perform any appropriate ones of or portions of the methods disclosed herein.

The computing device 4000 may include an interface device 4006 (e.g., one or more interface devices 4006). The interface device 4006 may include one or more communication chips, connectors, and/or other hardware and software to govern communications between the computing device 4000 and other computing devices. For example, the interface device 4006 may include circuitry for managing wireless communications for the transfer of data to and from the computing device 4000. The term "wireless" and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. Circuitry included in the interface device 4006 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as "3GPP2"), etc.). In some embodiments, circuitry included in the interface device 4006 for managing wireless communications may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 4006 for managing wireless communications may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 4006 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 4006 may include one or more antennas (e.g., one or more antenna arrays) to receipt and/or transmission of wireless communications.

In some embodiments, the interface device 4006 may include circuitry for managing wired communications, such as electrical, optical, or any other suitable communication protocols. For example, the interface device 4006 may include circuitry to support communications in accordance with Ethernet technologies. In some embodiments, the interface device 4006 may support both wireless and wired communication, and/or may support multiple wired communication protocols and/or multiple wireless communication protocols. For example, a first set of circuitry of the interface device 4006 may be dedicated to shorter-range wireless communications such as Wi-Fi or Bluetooth, and a second set of circuitry of the interface device 4006 may be dedicated to longer-range wireless communications such as global positioning system (GPS), EDGE, GPRS, CDMA, WiMAX, LTE, EV-DO, or others. In some embodiments, a first set of circuitry of the interface device 4006 may be dedicated to wireless communications, and a second set of circuitry of the interface device 4006 may be dedicated to wired communications.

The computing device 4000 may include battery/power circuitry 4008. The battery/power circuitry 4008 may include one or more energy storage devices (e.g., batteries or capacitors) and/or circuitry for coupling components of the computing device 4000 to an energy source separate from the computing device 4000 (e.g., AC line power).

The computing device 4000 may include a display device 4010 (e.g., multiple display devices). The display device 4010 may include any visual indicators, such as a heads-up display, a computer monitor, a projector, a touchscreen display, a liquid crystal display (LCD), a light-emitting diode display, or a flat panel display.

The computing device 4000 may include other input/output (I/O) devices 4012. The other I/O devices 4012 may include one or more audio output devices (e.g., speakers, headsets, earbuds, alarms, etc.), one or more audio input devices (e.g., microphones or microphone arrays), location devices (e.g., GPS devices in communication with a satellite-based system to receive a location of the computing device 4000, as known in the art), audio codecs, video codecs, printers, sensors (e.g., thermocouples or other temperature sensors, humidity sensors, pressure sensors, vibration sensors, accelerometers, gyroscopes, etc.), image capture devices such as cameras, keyboards, cursor control devices such as a mouse, a stylus, a trackball, or a touchpad, bar code readers, Quick Response (QR) code readers, or radio frequency identification (RFID) readers, for example. The other I/O devices 4012 may include one or more other electrical measurement devices to measure voltage and/or current for example of discharged ESD pulses and/or monitor electrical equipment being tested with the ESD simulator.

The computing device 4000 may have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer, etc.), a desktop computing device, or a server computing device or other networked computing component.

One or more computing devices implementing any of the ESD simulator support modules, apparatuses, or methods disclosed herein may be part of a ESD simulator support system. FIG. 10 is a block diagram of an example ESD simulator support system 5000 in which some or all of the ESD simulator support methods disclosed herein may be performed, in accordance with various embodiments. The ESD simulator support modules, apparatuses, and methods disclosed herein (e.g., the ESD simulator support apparatus 2000 of FIG. 6 and the method 2100 of FIG. 7) may be implemented by one or more of the ESD simulator 5010, the user local computing device 5020, the service local computing device 5030, or the remote computing device 5040 of the ESD simulator support system 5000.

Any of the ESD simulator 5010, the user local computing device 5020, the service local computing device 5030, or the remote computing device 5040 may include any of the embodiments of the computing device 4000 discussed herein with reference to FIG. 9, and any of the ESD simulator 5010, the user local computing device 5020, the service local computing device 5030, or the remote computing device 5040 may take the form of any appropriate ones of the embodiments of the computing device 4000 discussed herein with reference to FIG. 9.

The ESD simulator 5010, the user local computing device 5020, the service local computing device 5030, or the remote computing device 5040 may each include a processing device 5002, a storage device 5004, and an interface device 5006. The processing device 5002 may take any suitable form, including the form of any of the processing devices 4002 discussed herein with reference to FIG. 4, and the processing devices 5002 included in different ones of the ESD simulator 5010, the user local computing device 5020, the service local computing device 5030, or the remote computing device 5040 may take the same form or different forms. The storage device 5004 may take any suitable form, including the form of any of the storage devices 5004 discussed herein with reference to FIG. 4, and the storage devices 5004 included in different ones of the ESD simulator 5010, the user local computing device 5020, the service local computing device 5030, or the remote computing device 5040 may take the same form or different forms. The interface device 5006 may take any suitable form, including the form of any of the interface devices 4006 discussed herein with reference to FIG. 4, and the interface devices 5006 included in different ones of the ESD simulator 5010, the user local computing device 5020, the service local computing device 5030, or the remote computing device 5040 may take the same form or different forms.

The ESD simulator 5010, the user local computing device 5020, the service local computing device 5030, and the remote computing device 5040 may be in communication with other elements of the ESD simulator support system 5000 via communication pathways 5008. The communication pathways 5008 may communicatively couple the interface devices 5006 of different ones of the elements of the ESD simulator support system 5000, as shown, and may be wired or wireless communication pathways (e.g., in accordance with any of the communication techniques discussed herein with reference to the interface devices 4006 of the computing device 4000 of FIG. 9). The particular ESD simulator support system 5000 depicted in FIG. 10 includes communication pathways between each pair of the ESD simulator 5010, the user local computing device 5020, the service local computing device 5030, and the remote computing device 5040, but this “fully connected” implementation is simply illustrative, and in various embodiments, various ones of the communication pathways 5008 may be absent. For example, in some embodiments, a service local computing device 5030 may not have a direct communication pathway 5008 between its interface device 5006 and the interface device 5006 of the ESD simulator 5010, but may instead communicate with the ESD simulator 5010 via the communication pathway 5008 between the service local computing device 5030 and the user local computing device 5020 and the communication pathway 5008 between the user local computing device 5020 and the ESD simulator 5010.

The user local computing device 5020 may be a computing device (e.g., in accordance with any of the embodiments of the computing device 4000 discussed herein) that is local to a user of the ESD simulator 5010. In some embodiments, the user local computing device 5020 may also be local to the ESD simulator 5010, but this need not be the case; for example, a user local computing device 5020 that is in a user’s home or office may be remote from, but in communication with, the ESD simulator 5010 so that the user may use the user local computing device 5020 to control and/or access data from the ESD simulator 5010. In some embodiments, the user local computing device 5020 may be a laptop, smartphone, or tablet device. In some embodiments the user local computing device 5020 may be a portable computing device.

The service local computing device 5030 may be a computing device (e.g., in accordance with any of the embodiments of the computing device 4000 discussed herein) that is local to an entity that services the ESD simulator 5010. For example, the service local computing device 5030 may be local to a manufacturer of the ESD simulator 5010 or to a third-party service company. In some embodiments, the service local computing device 5030 may communicate with the ESD simulator 5010, the user local computing device 5020, and/or the remote computing device 5040 (e.g., via a direct communication pathway 5008 or via multiple “indirect” communication pathways 5008, as discussed above) to receive data regarding the operation of the ESD simulator 5010, the user local computing device 5020, and/or the remote computing device 5040 (e.g., the results of self-tests of the ESD simulator 5010, calibration coefficients used by the ESD simulator 5010, the measurements of sensors associated with the ESD simulator 5010, etc.). In some embodiments, the service local computing device 5030 may communicate with the ESD simulator 5010, the user local computing device 5020, and/or the remote computing device 5040 (e.g., via a direct communication pathway 5008 or via multiple “indirect” communication pathways 5008, as discussed above) to transmit data to the ESD simulator 5010, the user local computing device 5020, and/or the remote computing device 5040 (e.g., to update programmed instructions, such as firmware, in the ESD simulator 5010, to initiate the performance of test or calibration sequences in the ESD simulator 5010, to update programmed instructions, such as software, in the user local computing device 5020 or the remote computing device 5040, etc.). A user of the ESD simulator 5010 may utilize the ESD simulator 5010 or the user local computing device 5020 to communicate with the service local computing device 5030 to report a problem with the ESD simulator 5010 or the user local computing device 5020, to request a visit from a technician to improve the operation of the ESD simulator 5010, to order consumables or replacement parts associated with the ESD simulator 5010, or for other purposes.

The remote computing device 5040 may be a computing device (e.g., in accordance with any of the embodiments of the computing device 4000 discussed herein) that is remote from the ESD simulator 5010 and/or from the user local computing device 5020. In some embodiments, the remote computing device 5040 may be included in a datacenter or other large-scale server environment. In some embodiments, the remote computing device 5040 may include network-attached storage (e.g., as part of the storage device 5004). The remote computing device 5040 may store data generated by the ESD simulator 5010, perform analyses of the data generated by the ESD simulator 5010 (e.g., in accordance with programmed instructions), facilitate communication between the user local computing device 5020 and the ESD simulator 5010, and/or facilitate communication between the service local computing device 5030 and the ESD simulator 5010.

In some embodiments, one or more of the elements of the ESD simulator support system 5000 illustrated in FIG. 10 may not be present. Further, in some embodiments, multiple ones of various ones of the elements of the ESD simulator support system 5000 of FIG. 10 may be present. For example, an ESD simulator support system 5000 may include multiple user local computing devices 5020 (e.g., different user local computing devices 5020 associated with different users or in different locations). In another example, an ESD simulator support system 5000 may include multiple ESD simulators 5010, all in communication with service local computing device 5030 and/or a remote computing device 5040; in such an embodiment, the service local computing device 5030 may monitor these multiple ESD simulators 5010, and the service local computing device 5030 may cause updates or other information may be “broadcast” to multiple ESD simulators 5010 at the same time. Different ones of the ESD simulators 5010 in an ESD simulator support system 5000 may be located close to one another (e.g., in the same room) or farther from one another (e.g., on different floors of a building, in different buildings, in different cities, etc.). In some embodiments, a ESD simulator 5010 may be connected to an Internet-of-Things (IoT) stack that allows for command and control of the ESD simulator 5010 through a web-based application, a virtual or augmented reality application, a mobile application, and/or a desktop application. Any of these applications may be accessed by a user operating the user local computing device 5020 in communication with the ESD simulator 5010 by the intervening remote computing device 5040. In some embodiments, a ESD simulator 5010 may be sold by the manufacturer along with one or more associated user local computing devices 5020 as part of a local ESD simulator computing unit 5012.

The following paragraphs provide various examples of the embodiments disclosed herein.

Example 1 – An electrostatic discharge (ESD) simulator for discharging an ESD pulse to a device under test is disclosed. The ESD simulator comprises a gate driver, a switching circuit for controlling the discharge of the ESD pulse, wherein the switching circuit comprises at least one of a SiC or GaN transistor, and wherein the gate driver is connected to the switching circuit, and a programmable circuit component connected to the gate driver, wherein the programmable circuit component is adjustable, by a computing device, to change a current delivered to the switching circuit based on at least one of a desired pulse slew rate or desired pulse rise time defined by a user.

Example 2 - The ESD simulator of Example 1, wherein the programmable circuit component comprises a programmable power supply, and wherein a gate driver voltage of the gate driver is supplied by the programmable power supply and is adjustable, by the computing device, based on the at least one of the desired pulse slew rate or desired pulse rise time defined by the user.

Example 3 - The ESD simulator of any one of Examples 1 or 2, wherein the programmable circuit component comprises a programmable variable resistor, and wherein a resistance of the programmable variable resistor is adjustable, by the computing device, based on the at least one of the desired pulse slew rate or desired pulse rise time defined by the user.

Example 4 - The ESD simulator of any one of Examples 1-3, wherein adjustment of the programmable circuit component changes a switching behavior of the switching circuit to produce an ESD pulse that exhibits the at least one of the desired pulse slew rate or desired pulse rise time.

Example 5 - The ESD simulator of any one of Examples 1-4, wherein the at least one of the desired pulse slew rate or desired pulse rise time is defined by the user through a user interface on a display.

Example 6 - The ESD simulator of any one of Examples 1-5, wherein the at least one of the desired pulse slew rate or desired pulse rise time is defined by the user via a selection of a predefined testing slew rates or rise times.

Example 7 - The ESD simulator of any one of Examples 1-6, further comprising an ESD simulator support apparatus, comprising receiving logic to receive the at least one of the desired pulse slew rate or desired pulse rise time defined by the user, determining logic to determine a corresponding adjustment of the programmable circuit component that would result in the discharged ESD pulse exhibiting at least one of a pulse slew rate or a pulse rise time defined corresponding to the received desired pulse slew rate or desired pulse rise time, and adjusting logic to digitally adjust the programmable circuit component based on the determined corresponding adjustment.

Example 8 - The ESD simulator of Example 7, wherein the at least one of the desired pulse slew rate or desired pulse rise time defined by the user is manually defined by the user and does not correspond to a predefined slew rate or rise time.

Example 9 - The ESD simulator of any one of Examples 7 or 8, wherein the ESD simulator support apparatus further comprises discharging logic to discharge the ESD pulse after the programmable circuit component is adjusted.

Example 10 - The ESD simulator of any one of Examples 7-9, wherein the ESD simulator support apparatus further comprises feedback logic to measure at least one of an actual slew rate or actual rise time of the ESD pulse delivered to the device under test.

Example 11 - The ESD simulator of Example 10, wherein the adjusting logic recommends, to the user through a display, a further adjustment to the programmable circuit component to the user based on the measured at least one of the actual slew rate or actual rise time.

Example 12 - The ESD simulator of any one of Examples 10 or 11, wherein the determining logic is to further determine whether the measured at least one of the actual slew rate or actual rise time of the ESD pulse delivered to the device under test and the received at least one of the desired pulse slew rate or desired pulse rise time defined by the user are within an acceptable threshold of similarity, and wherein the adjusting logic is further to adjust the programmable circuit component based the determination that the measured at least one of the actual slew rate or actual rise time of the ESD pulse delivered to the device under test and the received at least one of the desired pulse slew rate or desired pulse rise time defined by the user are outside of the acceptable threshold of similarity.

Example 13 - The ESD simulator of any one of Examples 1-12, wherein an actual slew rate or actual rise time of the ESD pulse can be modified without switching to a different discharge network.

Example 14 - A electrostatic discharge (ESD) simulator support apparatus is disclosed. The ESD simulator support apparatus comprises receiving logic to receive an input from a user defining a desired value of at least one of a rise time or slew rate of an ESD pulse to be applied to a device under test, determining logic to determine an adjustment of at least one programmable circuit component to be made corresponding to the received desired value, adjusting logic to adjust the at least one programmable circuit component based on the determined adjustment, and discharging logic to discharge the ESD pulse after the at least one programmable circuit component is adjusted.

Example 15 - The ESD simulator support apparatus of Example 14, wherein the adjusting logic is to adjust an output of a programmable power supply to adjust a gate driver voltage.

Example 16 - The ESD simulator support apparatus of any one of Examples 14 or 15, further comprising feedback logic to measure at least one of an actual rise time or slew rate of the discharged ESD pulse.

Example 17 - The ESD simulator support apparatus of Example 16, further comprising displaying logic to displaying the measured at least one of the actual rise time or slew rate to the user.

Example 18 - An electrostatic discharge (ESD) simulator for delivering an ESD pulse to a device under test is disclosed. The ESD simulator comprises a programmable power supply, a gate driver comprising a gate driver voltage supplied by the programmable power supply, a switching circuit comprising at least one of a SiC transistor or a GaN transistor, wherein the switching circuit is connected to the gate driver and controls the delivery of the ESD pulse, and a computing device to receive a desired value of at least one of a rise time or slew rate of the ESD pulse to be discharged and, in response to receiving the desired value, digitally adjust the gate driver voltage of the gate driver to generate the ESD pulse which exhibits the desired value of the at least one of the rise time or slew rate.

Example 19 - The ESD simulator of Example 18, further comprising a display for displaying a measured value of at least one of the actual rise time or actual slew rate of the discharged ESD pulse.

1. An electrostatic discharge (ESD) simulator for discharging an ESD pulse to a device under test, the ESD simulator comprising:
a gate driver;
a switching circuit for controlling the discharge of the ESD pulse, wherein the switching circuit comprises at least one of a SiC or GaN transistor, and wherein the gate driver is connected to the switching circuit; and
a programmable circuit component connected to the gate driver, wherein the programmable circuit component is adjustable, by a computing device, to change a current delivered to the switching circuit based on at least one of a desired pulse slew rate or desired pulse rise time defined by a user.

2. The ESD simulator of claim 1, wherein the programmable circuit component comprises a programmable power supply, and wherein a gate driver voltage of the gate driver is supplied by the programmable power supply and is adjustable, by the computing device, based on the at least one of the desired pulse slew rate or desired pulse rise time defined by the user.

3. The ESD simulator of claim 1, wherein the programmable circuit component comprises a programmable variable resistor, and wherein a resistance of the programmable variable resistor is adjustable, by the computing device, based on the at least one of the desired pulse slew rate or desired pulse rise time defined by the user.

4. The ESD simulator of claim 1, wherein adjustment of the programmable circuit component changes a switching behavior of the switching circuit to produce an ESD pulse that exhibits the at least one of the desired pulse slew rate or desired pulse rise time.

5. The ESD simulator of claim 1, wherein the at least one of the desired pulse slew rate or desired pulse rise time is defined by the user through a user interface on a display.

6. The ESD simulator of claim 1, wherein the at least one of the desired pulse slew rate or desired pulse rise time is defined by the user via a selection of a predefined testing slew rates or rise times.

7. The ESD simulator of claim 1, further comprising an ESD simulator support apparatus, comprising:
receiving logic to receive the at least one of the desired pulse slew rate or desired pulse rise time defined by the user;
determining logic to determine a corresponding adjustment of the programmable circuit component that would result in the discharged ESD pulse exhibiting at least one of a pulse slew rate or a pulse rise time defined corresponding to the received desired pulse slew rate or desired pulse rise time; and
adjusting logic to digitally adjust the programmable circuit component based on the determined corresponding adjustment.

8. The ESD simulator of claim 7, wherein the at least one of the desired pulse slew rate or desired pulse rise time defined by the user is manually defined by the user and does not correspond to a predefined slew rate or rise time.

9. The ESD simulator of claim 7, wherein the ESD simulator support apparatus further comprises discharging logic to discharge the ESD pulse after the programmable circuit component is adjusted.

10. The ESD simulator of claim 7, wherein the ESD simulator support apparatus further comprises feedback logic to measure at least one of an actual slew rate or actual rise time of the ESD pulse delivered to the device under test.

11. The ESD simulator of claim 10, wherein the adjusting logic recommends, to the user through a display, a further adjustment to the programmable circuit component to the user based on the measured at least one of the actual slew rate or actual rise time.

12. The ESD simulator of claim 10, wherein the determining logic is to further determine whether the measured at least one of the actual slew rate or actual rise time of the ESD pulse delivered to the device under test and the received at least one of the desired pulse slew rate or desired pulse rise time defined by the user are within an acceptable threshold of similarity, and wherein the adjusting logic is further to adjust the programmable circuit component based the determination that the measured at least one of the actual slew rate or actual rise time of the ESD pulse delivered to the device under test and the received at least one of the desired pulse slew rate or desired pulse rise time defined by the user are outside of the acceptable threshold of similarity.

13. The ESD simulator of claim 1, wherein an actual slew rate or actual rise time of the ESD pulse can be modified without switching to a different discharge network.

14. A electrostatic discharge (ESD) simulator support apparatus, comprising:
receiving logic to receive an input from a user defining a desired value of at least one of a rise time or slew rate of an ESD pulse to be applied to a device under test;
determining logic to determine an adjustment of at least one programmable circuit component to be made corresponding to the received desired value;
adjusting logic to adjust the at least one programmable circuit component based on the determined adjustment; and
discharging logic to discharge the ESD pulse after the at least one programmable circuit component is adjusted.

15. The ESD simulator support apparatus of claim 14, wherein the adjusting logic is to adjust an output of a programmable power supply to adjust a gate driver voltage.

16. The ESD simulator support apparatus of claim 14, further comprising feedback logic to measure at least one of an actual rise time or slew rate of the discharged ESD pulse.

17. The ESD simulator support apparatus of claim 16, further comprising displaying logic to displaying the measured at least one of the actual rise time or slew rate to the user.

18. An electrostatic discharge (ESD) simulator for delivering an ESD pulse to a device under test, the ESD simulator comprising:
a programmable power supply;
a gate driver comprising a gate driver voltage supplied by the programmable power supply;
a switching circuit comprising at least one of a SiC transistor or a GaN transistor, wherein the switching circuit is connected to the gate driver and controls the delivery of the ESD pulse; and
a computing device to receive a desired value of at least one of a rise time or slew rate of the ESD pulse to be discharged and, in response to receiving the desired value, digitally adjust the gate driver voltage of the gate driver to generate the ESD pulse which exhibits the desired value of the at least one of the rise time or slew rate.

19. The ESD simulator of claim 18, further comprising a display for displaying a measured value of at least one of the actual rise time or actual slew rate of the discharged ESD pulse.
